(19) United States
(12) Patent Application Publication
(10) Pub. No.: US 2014/0083501 A1
(43) Pub. Date: Mar. 27, 2014

(54) TRANSPARENT CONDUCTING FILM HAVING DOUBLE STRUCTURE AND METHOD OF MANUFACTURING THE SAME

(71) Applicants: Jun-Sik Cho, Daejeon (KR); Sang-Hyun Park, Daejeon (KR); Jae-Ho Yun, Daejeon (KR); Joo-Hyung Park, Daejeon (KR); Kee-Shik Shin, Daejeon (KR); Jin-Su Yoo, Seoul (KR); Kyung-Hoon Yoon, Daejeon (KR)

(72) Inventors: Jun-Sik Cho, Daejeon (KR); Sang-Hyun Park, Daejeon (KR); Jae-Ho Yun, Daejeon (KR); Joo-Hyung Park, Daejeon (KR); Kee-Shik Shin, Daejeon (KR); Jin-Su Yoo, Seoul (KR); Kyung-Hoon Yoon, Daejeon (KR)

(73) Assignee: Korea Institute of Energy Research, Daejeon (KR)

(21) Appl. No.: 14/118,522

(22) PCT Filed: Aug. 14, 2012
(86) PCT No.: PCT/KR2012/006462

§ 371 Date: Nov. 18, 2013

(30) Foreign Application Priority Data
Sep. 28, 2011 (KR) 10-2011-0098571

(51) Int. Cl. H01L 31/0216; H01L 31/18

(52) U.S. Cl. CPC H01L 31/02168; H01L 31/1888
USPC 136/256; 438/98

(57) ABSTRACT

Disclosed is a double-structure transparent conducting film having both excellent electrical characteristics and excellent light trapping performance, and a method of manufacturing the same.

The double-structure transparent conducting film, which is used as a front antireflection film, a front electrode or a rear reflective film of a solar cell, includes: a light transmitting layer; and a light trapping layer whose one side is in contact with the light transmitting layer and whose other side is provided thereon with a surface textured structure; wherein the relationship of electrical conductivity A of the light transmitting layer and electrical conductivity a of the light trapping layer is A>a, and the relationship of etchability of the light transmitting layer and etchability of the light trapping layer is B<b.

### CROSS-REFERENCE TO RELATED APPLICATION(S)

This Application is a 371 National Stage Application of International Application No. PCT/KR2012/006462, filed on Aug. 14, 2012, published as International Publication No. WO2013/048006, which claims priority to Korean Patent Application No. 10-2011-0098571, filed on Sep. 28, 2011, the contents of which are incorporated by reference in their entireties.

### TECHNICAL FIELD

The present invention relates to a transparent conducting film used as a front antireflection film, a front electrode or a rear reflective film of a solar cell, and a method of manufacturing the same. More particularly, the present invention relates to a transparent conducting film having both excellent electrical characteristics and excellent light trapping performance, and a method of manufacturing the same.

### BACKGROUND ART

Generally, solar cells use p-n junction diodes, and are classified into various types according to the kind of materials used as a light absorbing layer. Particularly, solar cells using a light absorbing layer made of silicon are classified into crystalline substrate-type solar cells and amorphous thin film-type solar cells. Crystalline substrate-type solar cells are problematic in that the production cost thereof is high because a silicon wafer is used. However, amorphous thin film-type solar cells are increasingly attracting considerable attention because they can use a small amount of silicon and can be applied to exterior surface materials of buildings or mobile appliances.

In particular, thin film-type solar cells are generally referred to as solar cells that use a material such as CdTe, CdS, CIS, CIGS or the like in the form of thin film. Recently, a tandem solar cell stacked with two or more thin film-type solar cells was developed, and thus research into thin film-type solar cells has actively been conducted.

Such thin film-type solar cells are fabricated by applying a thin film onto a substrate, and are classified into superstrate solar cells and substrate solar cells according to the incident direction of solar light. The superstrate solar cell is configured such that solar light is introduced through a substrate, and such that a front electrode is formed on a transparent glass substrate, a light absorbing layer is formed on the front electrode and then a rear reflective film is finally formed on the light absorbing layer. The substrate solar cell is configured such that solar light is introduced through the opposite side of a substrate, and such that a light absorbing layer is formed on a metal substrate serving as a rear reflective film and then a front electrode is finally formed on the light absorbing layer.

Meanwhile, as a method for increasing the efficiency of a solar cell, a light trapping technology for increasing the usage rate of incident solar light is necessarily used, wherein fine surface unevenness, having pyramid-shaped structures or the like, is formed on the front side or rear side of a solar cell to form a textured structure for inducing the scattering or total reflection of incident solar light.

In the case of a crystalline silicon solar cell, particularly, a monocrystalline silicon solar cell, a method of forming a textured structure on a silicon substrate using the nonuniform etching characteristics of silicon has been further developed.

However, in the case of a thin film-type solar cell using a substrate made of glass, a metal or a polymer, a light trapping technology has not been further developed in accordance with the method of forming a textured structure.

In order to increase the light trapping performance of a thin film-type solar cell, a technology of using a textured glass substrate (refer to the prior art document 1) or a technology of forming a textured structure on the surface of a metal substrate was proposed. However, this technology is problematic in that it is difficult to form a textured structure on the surface of a glass substrate or a metal substrate.

Recently, efforts have been made to form a textured structure even on a transparent conducting film deposited on a substrate, and a technology of fowling a textured structure on a ZnO-based transparent conducting film (refer to the prior art document 2) has been proposed. However, these technologies are also problematic in that satisfactory light trapping efficiency cannot be exhibited.

In a superstate thin film solar cell, a transparent conducting film formed on a glass substrate is used as a front electrode, and solar light transmitted through the front electrode is scattered by a textured structure formed on the surface of the front electrode to increase the path length of incident light in a light absorbing layer, thereby increasing light absorbance. Further, in a substrate thin film solar cell, a transparent conducting film formed on a metal substrate is used as a rear reflective film serving to maximize the absorption of incident light by reflecting the incident light not absorbed in the light absorbing layer to the light absorbing layer again together with the metal substrate, and is used to increase the path length of incident light by scattering the light reflected from the rear reflective film through the textured structure of the surface of the rear reflective film.

Particularly, the total transmittance of a solar cell consists of specular transmittance and diffuse transmittance, and the increase of diffuse transmittance is required in order to improve the diffuse characteristics of light in a front electrode. Further, the total reflectance of a solar cell consists of specular reflectance and diffuse reflectance, and the increase of diffuse reflectance is required in order to improve the diffuse characteristics of light in a rear reflective film. Such diffuse transmittance and diffuse reflectance are closely related to the wavelength of incident light and the surface shape and surface roughness of a front electrode. Generally, since short-wavelength incident light is mostly absorbed in a range adjacent to a P-type layer and an I-type layer, it is important to maximize the diffuse transmittance or diffuse reflectance of a front electrode or a rear reflective film to a visible light region (500˜800 nm) and a long-wavelength region (800˜1000 nm). In order to improve the diffuse transmittance or diffuse reflectance of a front electrode or a rear reflective film to a visible light region and a long-wavelength region, the change in surface shape and surface roughness comparable to the change in wavelength of the incident light is required. However, most of currently-used transparent conducting materials do not have high light trapping efficiency because they cannot assure sufficient surface roughness due to their low etchability.

### DISCLOSURE

### Technical Problem

Accordingly, the present invention has been devised to solve the above-mentioned problems, and an object of the present invention is to provide a transparent conducting film which has excellent light trapping performance because of the formation of a textured structure due to its good surface etchability and which has excellent electrical and optical characteristics, and a method of manufacturing the same.

### Technical Solution

In order to accomplish the above object, an aspect of the present invention provides a double-structure transparent conducting film, which is used as a front antireflection film, a front electrode or a rear reflective film of a solar cell, including: a light transmitting layer; and a light trapping layer whose one side is in contact with the light transmitting layer and whose other side is provided thereon with a surface textured structure; wherein the relationship of electrical conductivity A of the light transmitting layer and electrical conductivity a of the light trapping layer is A>a, and the relationship of etchability of the light transmitting layer and etchability of the light trapping layer is B<b.

In this case, the other side of the light trapping layer, which is provided thereon with the surface textured structure, may have a surface roughness of 50 nm or more. When the surface roughness thereof is 50 nm or more, the diffuse transmittance and diffuse reflectance of the double-structure transparent conducting film are improved compared to those of a general transparent conducting film.

Further, the light trapping layer may be formed by depositing a ZnO-based transparent conducting thin film at a temperature of lower than 300° C.

The present inventors have conducted research into ZnO that can form a surface textured structure using wet etching, and have paid attention to the fact that the physical properties, including etchability, of the transparent conducting film are changed depending on the formation conditions of a ZnO thin film.

Particularly, the ZnO thin film is characterized in that its electrical characteristics are poor when it can easily form a surface textured structure by nonuniform etching due to its excellent etchability, and in that, when its electrical characteristics are good, it is difficult to form a surface textured structure by nonuniform etching due to its poor etchability. Based on these findings, the present inventors have developed a double-structure transparent conducting film including: a light transmitting layer which is a transparent thin film having excellent electrical characteristics; and a light trapping layer which is a ZnO-based transparent conducting thin film that can easily form a surface textured structure, wherein one side of the light trapping layer is provided with a surface textured structure by wet etching.

Here, the light transmitting layer may be formed by depositing a ZnO-based transparent conducting thin film at a temperature of 300° C. or higher, or may be formed by depositing a transparent conducting thin film other than the ZnO-based transparent conducting thin film. The light transmitting layer is formed at higher temperature than the light trapping layer.

Since the light transmitting layer needs high electrical conductivity and high optical transmittance, a commonly-used transparent conducting thin film may be used as the light transmitting layer. In the case where a ZnO-based transparent conducting thin film is used as the light transmitting layer, when the light transmitting layer is formed at a temperature of 300° C. or higher, which is higher than the formation temperature of the light trapping layer, the electrical conductivity and optical transmittance of the light transmitting layer are excellent compared to those of the light trapping layer.

Another aspect of the present invention provides a method of manufacturing a double-structure transparent conducting film, which is used as a front antireflection film, a front electrode or a rear reflective film of a solar cell, including the steps of forming a light transmitting layer on a substrate; forming a light trapping layer on the light transmitting layer; and etching a surface of the light trapping layer to form a surface textured structure, wherein the relationship of electrical conductivity A of the light transmitting layer and electrical conductivity a of the light trapping layer is A>a, and the relationship of etchability of the light transmitting layer and etchability of the light trapping layer is B<b.

In this case, in the step of forming the light trapping layer, when the light trapping layer is deposited to a thickness of 300 nm or more, the surface textured structure formed by etching may have surface roughness suitable for diffuse transmittance at a wavelength rang of 400˜1100 nm.

Preferably, the step of forming the light trapping layer may be performed by depositing a ZnO-based transparent conducting thin film at a temperature of lower than 300° C.

Further, the step of forming the light transmitting layer is performed by depositing a ZnO-based transparent conducting thin film at a temperature of 300° C. or higher. In this case, the step of forming the light transmitting layer is continuously connected to the step of forming the light trapping layer by continuously adjusting deposition temperature.

Meanwhile, the step of forming the light transmitting layer may be performed by depositing a transparent conducting thin film, other than the ZnO-based transparent conducting thin film.

Moreover, the step of forming the surface textured structure is performed by wet etching. The wet etching may use at least one selected from among acidic solutions including 0.1˜10% HCl or H₂C₂O₄.

Still another aspect of the present invention provides a method of manufacturing a double-structure transparent conducting film, which is used as a front antireflection film, a front electrode or a rear reflective film of a solar cell, including the steps of: depositing a ZnO-based transparent conducting thin film on a substrate at a temperature of 300° C. or higher to form a light transmitting layer; and depositing a ZnO-based transparent conducting thin film on the light transmitting layer at a temperature of lower than 300° C. to form a light trapping layer, wherein the step of forming the light transmitting layer and the step of forming the light trapping layer are performed by chemical deposition to allow a surface textured structure itself to be naturally formed.

When chemical deposition is used, since the surface shape of the light transmitting layer or the light trapping layer is not uniform, the surface textured structure is naturally formed thereon. When the ZnO-based transparent conducting thin film is deposited at a temperature of lower than 300° C. by chemical deposition, the surface roughness thereof become high.

In this case, a chemical vapor deposition (CVD) method or a sol-gel method may be used as the chemical deposition.

### Advantageous Effects

As described above, since the transparent conducting film for a solar cell according to the present invention includes a light absorbing layer that has excellent electrical characteristics and high optical transmittance and a light trapping layer that can easily form a surface textured structure, it can exhibit both excellent electrical characteristics and excellent light trapping performance.

Finally, the conversion efficiency of a solar cell can be improved because the transparent conducting film having both excellent electrical characteristics and excellent light trapping performance is used.

### DESCRIPTION OF DRAWINGS

FIG. 1 is a cross-sectional view showing a transparent conducting film having a double structure according to an embodiment of the present invention.

FIG. 2 shows photographs of surfaces of a transparent conducting film of Comparative Example 1 before and after etching.

FIG. 3 shows photographs of cross sections of a transparent conducting film of Comparative Example 1 before and after etching.

FIG. 4 is a graph showing the total transmittance and diffuse transmittance of a transparent conducting film of Comparative Example 1 after etching.

FIG. 5 shows photographs of surfaces of a transparent conducting film of Comparative Example 2 before and after etching.

FIG. 6 is a graph showing the total transmittance and diffuse transmittance of a transparent conducting film of Comparative Example 2 after etching.

FIG. 7 shows photographs of surfaces of a transparent conducting film of Example 1 before and after etching.

FIG. 8 shows photographs of cross sections of a transparent conducting film of Example 1 before and after etching.

FIG. 9 is a graph showing the total transmittance and diffuse transmittance of a transparent conducting film of Example 1 after etching.

### MODE FOR INVENTION

Hereinafter, the present invention will be described in detail with reference to the accompanying drawings.

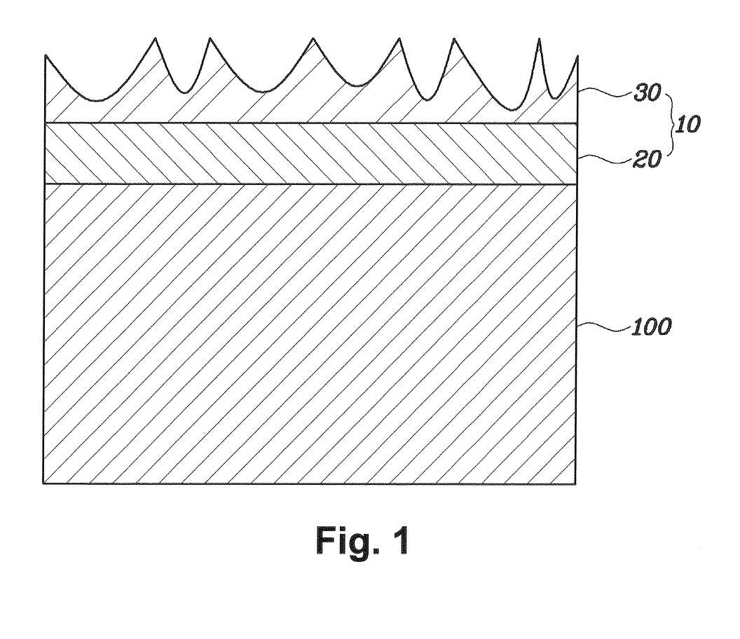

FIG. 1 is a cross-sectional view showing a transparent conducting film having a double structure according to an embodiment of the present invention.

The transparent conducting film 10 includes a light transmitting layer 20 and a light trapping layer 30, which are sequentially formed on a substrate 100.

In the case of a superstrate thin film-type solar cell, the substrate 100 may be a transparent substrate such as a glass substrate or the like, and, in the case of a substrate thin film-type solar cell, the substrate 100 may be a metal or polymer substrate provided with a metal layer.

The light transmitting layer 20 is a transparent conducting film deposited on the substrate 100, and is made of a material having excellent electrical characteristics and high optical transmittance without regard to characteristics for forming a surface textured structure.

The raw material of the light transmitting layer 20 may be freely selected from transparent conductive oxides (TCOs) such as ITO and the like. In the case of a ZnO-based transparent conducting film, the deposition of the ZnO-based transparent conducting film may be performed at high temperature (300° C. or higher).

The light trapping layer 30 is a transparent conducting film deposited on the light transmitting layer 20, and is made of a material having excellent etchability for forming a surface textured structure, compared to a material having excellent electrical characteristics and high optical transmittance. Typically, a ZnO-based transparent conducting film deposited at low temperature (lower than 300° C.) is used as the light trapping layer 30. One side of the light trapping layer 30 is provided with a surface textured structure formed by etching.

The ZnO-based transparent conducting film is a ZnO thin film doped with Al, Ga, B or the like in an amount of 0.1˜10 wt %, and may be deposited by DC or RF magnetron sputtering, electron beam evaporation or thermal evaporation or the like. The physical properties of the ZnO-based transparent conducting film are changed depending on deposition conditions, particularly, substrate temperature during film deposition. When the substrate temperature is high, the electrical conductivity and optical transmittance of the ZnO-based transparent conducting film are excellent, whereas the etchability thereof is poor. Further, when the substrate temperature is low, the electrical conductivity and optical transmittance thereof are poor, whereas the etchability thereof is improved.

Particularly, when the deposition temperature of the ZnO-based transparent conducting film is about 300° C., the ZnO-based transparent conducting film can obtain surface shape and surface roughness suitable for diffuse transmittance and diffuse reflectance characteristics in a wavelength range of 400˜1100 nm by wet etching. For this purpose, the ZnO-based transparent conducting film must be deposited to a thickness of at least 300 nm.

Hereinafter, the present invention will be described in more detail with reference to the following Examples.

### Comparative Example 1

On the assumption that a single-layer front electrode was formed, a single-layer (ZnO:Al) transparent conducting film was deposited on a glass substrate using RF magnetron sputtering under the following conditions.

TABLE 1

| | | | Deposition | |
|---|---|---|---|---|
| | Deposition | Deposition | power | Film |
| Target | pressure | temperature | density | thickness |
| Al-doped ZnO | 1.5 mTorr | 100° C. | 1.5 W/cm² | 1 μm |
| (1.5 wt % Al₂O₃) | | | | |

Subsequently, the transparent conducting film was wet-etched for 70 seconds using 0.5% HCl.

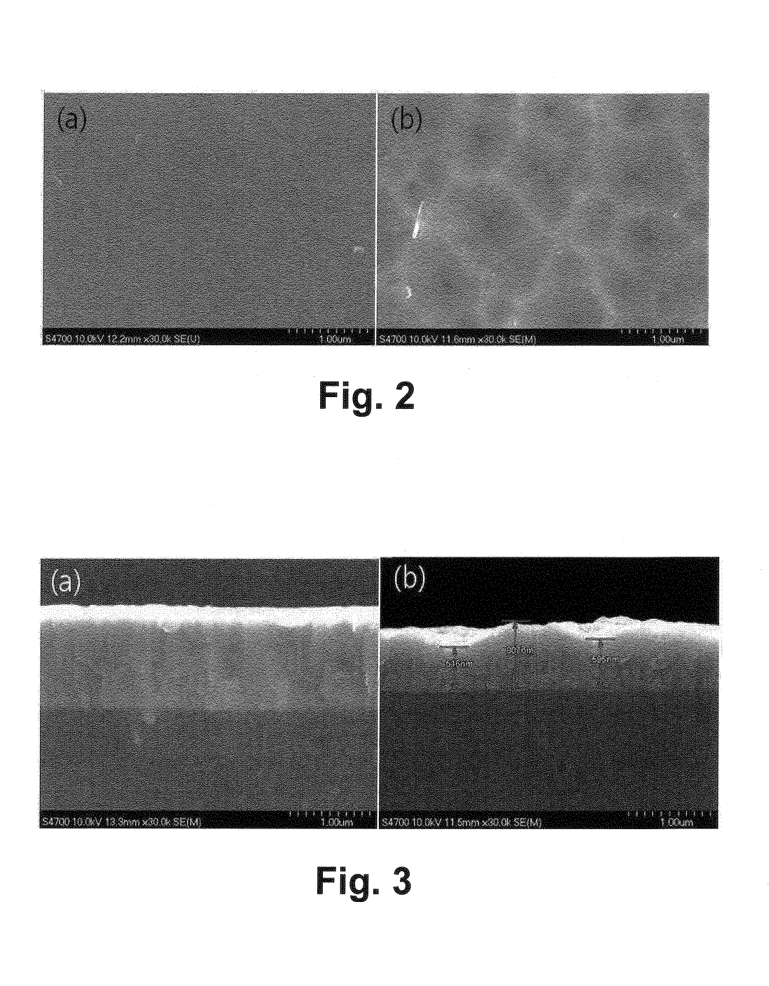

FIG. 2 shows photographs of surfaces of the transparent conducting film of Comparative Example 1 before (a) and after etching (b), and FIG. 3 shows photographs of cross sections of the transparent conducting film of Comparative Example 1 before (a) and after etching (b).

As shown in FIGS. 2 and 3, it can be ascertained that, before etching, the surface of the test sample was smooth, but, after etching, the test sample was wet-etched in the form of crater to be configured such that the thickness of a thick portion thereof is 807 nm, whereas the thickness of a thin portion thereof is 516 nm or 596 nm, that is, the difference in thickness between the thick and thin portions thereof is large.

The physical properties of the transparent conducting film, which were measured before and after etching, are as follows.

TABLE 2

| | Before etching | After etching |
|---|---|---|
| Surface resistance (Ω/sq) | 5.5 | 15 |
| Surface roughness (rms roughness, nm) | 6.8 | 107 |

From Table 2 above, it can be ascertained that the surface resistance and surface roughness of the test sample are represented by large values by nonuniform etching.

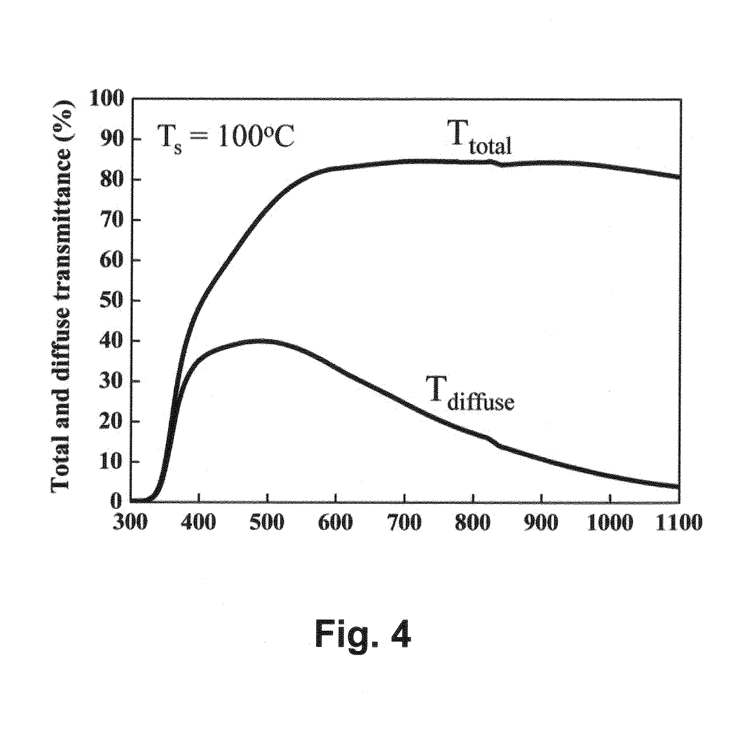

FIG. 4 is a graph showing the total transmittance and diffuse transmittance of the transparent conducting film of Comparative Example 1 after etching.

As shown in FIG. 4, it can be ascertained that the transparent conducting film of Comparative Example 1 has an average diffuse transmittance of 21.8% at a wavelength range of 400˜1100 nm.

### Comparative Example 2

On the assumption that a single-layer front electrode was formed, a single-layer (ZnO:Al) transparent conducting film was deposited on a glass substrate using RF magnetron sputtering under the following conditions.

TABLE 3

| | | | Deposition | |
|---|---|---|---|---|
| | Deposition | Deposition | power | Film |
| Target | pressure | temperature | density | thickness |
| Al-doped ZnO | 1.5 mTorr | 300° C. | 1.5 W/cm² | 1 μm |
| (1.5 wt % Al₂O₃) | | | | |

Subsequently, the transparent conducting film was wet-etched for 90 seconds using 0.5% HCl.

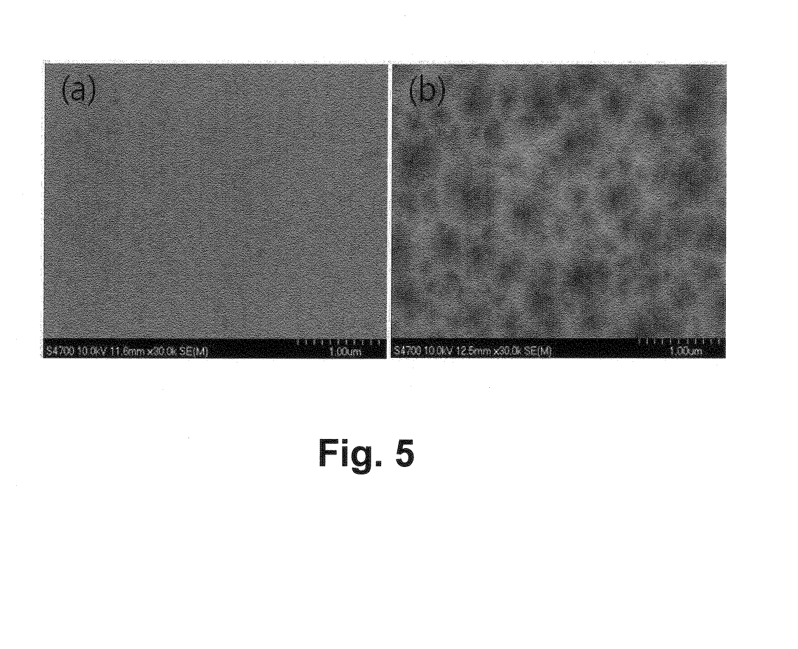

FIG. 5 shows photographs of surfaces of the transparent conducting film of Comparative Example 2 before (a) and after etching (b).

As shown in FIGS. 2 and 3, it can be ascertained that, before etching, the surface of the test sample was smooth, and the test sample was nonuniformly etched by wet etching, but the etching depth of this test sample was smaller than that of the test sample of Comparative Example 1.

The physical properties of the transparent conducting film, which were measured before and after etching, are as follows.

TABLE 4

| | Before etching | After etching |
|---|---|---|
| Surface resistance (Ω/sq) | 3.4 | 10.7 |
| Surface roughness (rms roughness, nm) | 5.6 | 23.3 |

From Table 4 above, it can be ascertained that the surface resistance and surface roughness of this test sample were lower than those of the test sample of Comparative Example 1 even before etching, and that the increments in surface resistance and surface roughness of this test sample were smaller than those in surface resistance and surface roughness of the test sample of Comparative Example 1.

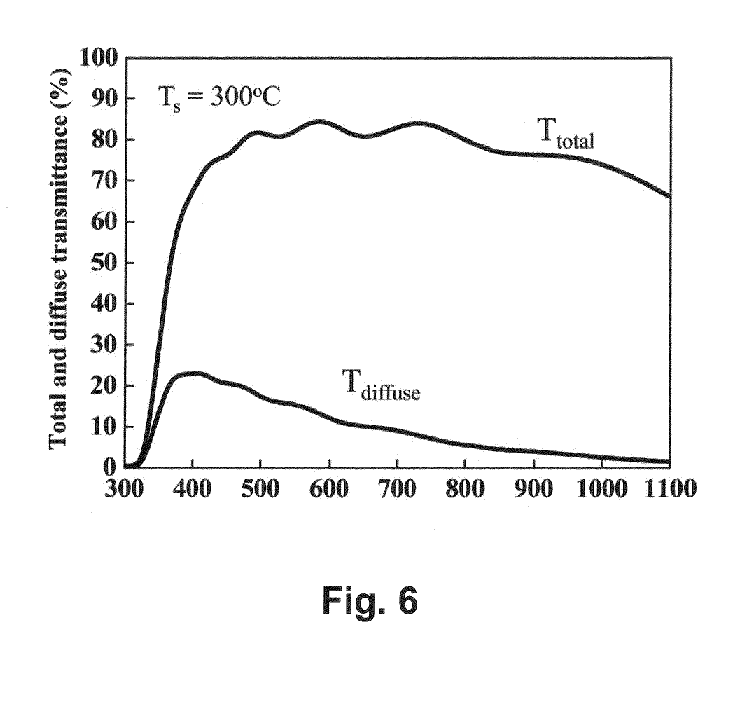

FIG. 6 is a graph showing the total transmittance and diffuse transmittance of the transparent conducting film of Comparative Example 2 after etching.

As shown in FIG. 6, it can be ascertained that the transparent conducting film of Comparative Example 2 has an average diffuse transmittance of 9.0% at a wavelength range of 400˜1100 nm.

### Example 1

On the assumption that a transparent conducting film having a double structure according to the present invention was applied to a front electrode, a double-layer (ZnO:Al) transparent conducting film was deposited on a glass substrate using RF magnetron sputtering under the following conditions.

TABLE 5

| | | | | Deposition | |
|---|---|---|---|---|---|
| Deposition | | Deposition | Deposition | power | Film |
| order | Target | pressure | temperature | density | thickness |
| Light | Al- | 1.5 mTorr | 300° C. | 1.5 W/cm² | 500 nm |
| transmitting | doped | | | | |
| layer | ZnO | | | | |
| | (1.5 | | | | |
| | wt % | | | | |
| | Al₂O₃) | | | | |
| Light | Al- | 1.5 mTorr | 100° C. | 1.5 W/cm² | 500 nm |
| trapping | doped | | | | |
| layer | ZnO | | | | |
| | (1.5 | | | | |
| | wt % | | | | |
| | Al₂O₃) | | | | |

Subsequently, a light trapping layer formed on the transparent conducting film was wet-etched for 70 seconds using 0.5% HCl.

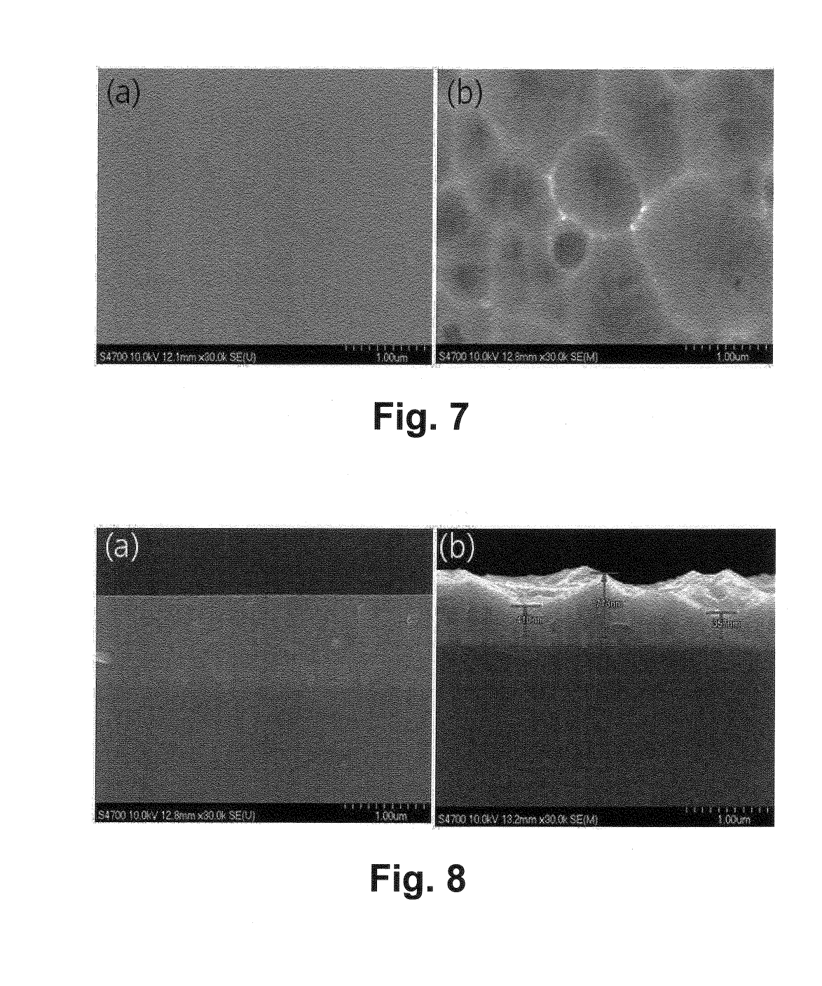

FIG. 7 shows photographs of surfaces of the transparent conducting film of Example 1 before (a) and after etching (b), and FIG. 8 shows photographs of cross sections of the transparent conducting film of Example 1 before (a) and after etching (b).

As shown in FIGS. 7 and 8, it can be ascertained that, before etching, the surface of the test sample was smooth, but, after etching, the test sample was wet-etched in the form of crater to be configured such that the thickness of a thick portion thereof is 773 nm, whereas the thickness of a thin portion thereof is 410 nm or 357 nm, that is, the difference in thickness between the thick and thin portions thereof is large.

The physical properties of the transparent conducting film, which were measured before and after etching, are as follows.

TABLE 6

| | Before etching | After etching |
|---|---|---|
| Surface resistance (Ω/sq) | 3.4 | 9.7 |
| Surface roughness (rms roughness, nm) | 6.5 | 156 |

From Table 6 above, it can be ascertained that the surface resistance and surface roughness of the test sample are represented by large values by nonuniform etching.

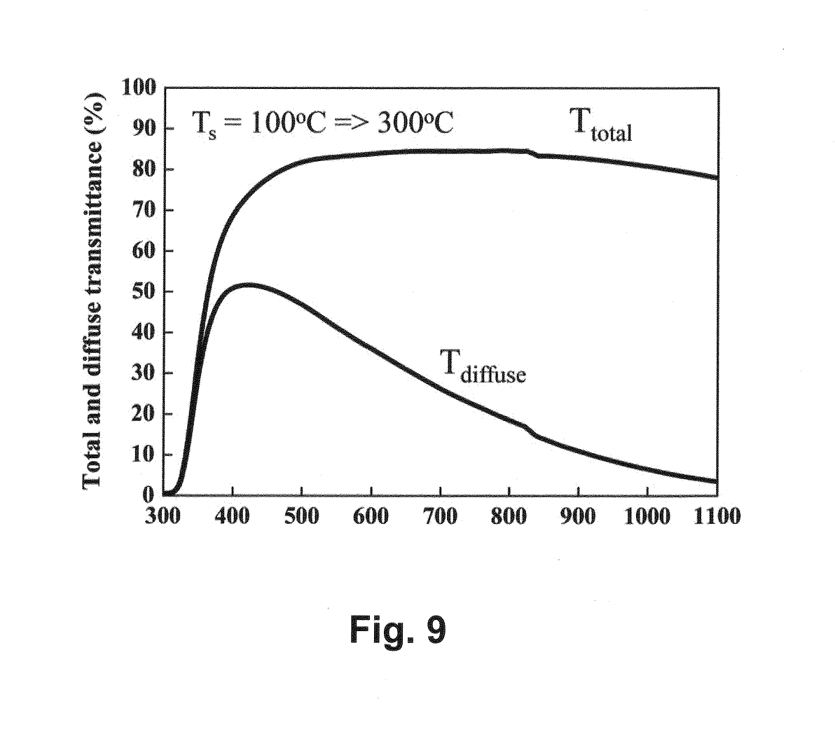

FIG. 9 is a graph showing the total transmittance and diffuse transmittance of the transparent conducting film of Example 1 after etching.

As shown in FIG. 9, it can be ascertained that the transparent conducting film of Example 1 has an average diffuse transmittance of 24.7% at a wavelength range of 400˜1100 nm.

Analyzing the above results, when the temperature of a substrate is low during the ZnO film deposition (Comparative Example 1), the surface roughness of the transparent conducting film of Comparative Example 1 was greatly increased to 107 nm, and the average diffuse transmittance thereof at a wavelength range of 400˜1100 nm was 21.8%, which was high, but there is a disadvantage in that the surface resistance thereof was 15Ω/sq, which was also high.

Conversely, when the temperature of a substrate is high during the ZnO film deposition (Comparative Example 2), the transparent conducting film of Comparative Example 2 had a low surface resistance of 10.7Ω/sq even after etching, whereas its surface roughness was 23.3 nm, which was not greatly increased, even after it was etched for a long period of time, compared to the transparent conducting film of Comparative Example 1, and its average diffuse transmittance at a wavelength range of 400˜1100 nm was 9.0%, which was low.

Consequently, a general monolayered transparent conducting ZnO film with doping impurity has one of excellent diffuse transmittance and surface resistance, whereas it has another poor property.

In contrast to the transparent conducting films of Comparative Examples 1 and 2, the transparent conducting film of Example 1 had a low surface resistance of 9.7Ω/sq even after etching, its surface roughness was greatly increased to 156 nm by etching, and it had a high average diffuse transmittance of 24.7% at a wavelength range of 400˜1100 nm, thereby exhibiting excellent electrical characteristics and light trapping performance.

According to another embodiment of the present invention, a double-structure transparent conducting film may be manufactured by a process including the steps of: depositing an ITO (indium tin oxide) thin film or a fluorine-doped tin oxide thin film on a glass substrate to form a light transmitting layer having excellent electrical conductivity and optical transmittance; depositing an Al-doped ZnO thin film on the light transmitting layer at a substrate temperature of 100° C. to form a light trapping layer; and wet-etching the light trapping layer using a HCl solution.

According to still another embodiment of the present invention, the above double-structure transparent conducting film may be formed on a metal layer formed on a metal or plastic substrate, not a glass substrate. In this case, the double-structure transparent conducting film of the present invention may be used as a rear reflective film.

Further, as a dopant for a ZnO-based transparent conducting thin film, Ga, B or the like may be used instead of Al. The amount of the dopant may be adjusted in the rage of 0.1˜10 wt %. The deposition of the ZnO-based transparent conducting thin film may be performed at a deposition pressure of 0.5 mTorr˜10 mTorr. Only when the light trapping layer has a thickness of 300 nm or more, sufficient surface roughness can be obtained by wet etching.

Further, as the method of depositing a transparent conducting film, DC sputtering, e-beam evaporation or thermal evaporation may be used instead of RF sputtering.

Moreover, as an etching solution for wet-etching the light trapping layer, a H₂C₂O₄ solution may be used instead of a HCl solution.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention. Accordingly, any and all modifications, variations or equivalent arrangements should be considered to be within the scope of the invention, and the detailed scope of the invention will be disclosed by the accompanying claims.

1. A double-structure transparent conducting film, which is used as a front antireflection film, a front electrode or a rear reflective film of a solar cell, comprising:
a light transmitting layer; and
a light trapping layer whose one side is in contact with the light transmitting layer and whose other side is provided thereon with a surface textured structure;
wherein a relationship of electrical conductivity A of the light transmitting layer and electrical conductivity a of the light trapping layer is A>a, and a relationship of etchability of the light transmitting layer and etchability of the light trapping layer is B<b.

2. The double-structure transparent conducting film of claim 1, wherein the other side of the light trapping layer, which is provided thereon with the surface textured structure, has a surface roughness of 50 nm or more.

3. The double-structure transparent conducting film of claim 2, wherein the light trapping layer is a ZnO-based transparent conducting thin film deposited at a temperature of lower than 300° C.

4. The double-structure transparent conducting film of claim 3, wherein the light transmitting layer is a ZnO-based transparent conducting thin film deposited at a temperature of 300° C. or higher.

5. The double-structure transparent conducting film of claim 3, wherein the light transmitting layer is a transparent conducting thin film, other than the ZnO-based transparent conducting thin film.

6. A method of manufacturing a double-structure transparent conducting film, which is used as a front antireflection film, a front electrode or a rear reflective film of a solar cell, comprising the steps of:
forming a light transmitting layer on a substrate;
forming a light trapping layer on the light transmitting layer; and
etching a surface of the light trapping layer to form a surface textured structure,
wherein a relationship of electrical conductivity A of the light transmitting layer and electrical conductivity a of the light trapping layer is A>a, and a relationship of etchability of the light transmitting layer and etchability of the light trapping layer is B<b.

7. The method of claim 6, wherein, in the step of forming the light trapping layer, the light trapping layer is deposited to a thickness of 300 nm or more.

8. The method of claim 6, wherein the step of forming the light trapping layer is performed by depositing a ZnO-based transparent conducting thin film at a temperature of lower than 300° C.

9. The method of claim 8, wherein the step of forming the light transmitting layer is performed by depositing a ZnO-based transparent conducting thin film at a temperature of 300° C. or higher.

10. The method of claim 9, wherein the step of forming the light transmitting layer is continuously connected to the step of forming the light trapping layer by lowering deposition temperature.

11. The method of claim 8, wherein the step of forming the light transmitting layer is performed by depositing a transparent conducting thin film, other than the ZnO-based transparent conducting thin film.

12. The method of claim 6, wherein the step of forming the surface textured structure is performed by wet etching.

13. The method of claim 12, wherein the wet etching uses an acidic solution of 0.1˜10% HCl or H₂C₂O₄.

14. A method of manufacturing a double-structure transparent conducting film, which is used as a front antireflection film, a front electrode or a rear reflective film of a solar cell, comprising the steps of:
depositing a ZnO-based transparent conducting thin film on a substrate at a temperature of 300° C. or higher to form a light transmitting layer; and
depositing a ZnO-based transparent conducting thin film on the light transmitting layer at a temperature of lower than 300° C. to form a light trapping layer,
wherein the step of forming the light transmitting layer and the step of forming the light trapping layer are performed by chemical deposition to allow a surface textured structure itself to be naturally formed.

15. The method of claim 14, wherein the chemical deposition is a chemical vapor deposition (CVD) method or a sol-gel method.
